(19) United States
(12) Patent Application Publication
(10) Pub. No.: US 2023/0115102 A1
(43) Pub. Date: Apr. 13, 2023

(54) INLINE CONTACTLESS METROLOGY CHAMBER AND ASSOCIATED METHOD

(71) Applicant: TEXAS INSTRUMENTS INCORPORATED, Dallas, TX (US)

(72) Inventors: Sebastian Meier, MUENCHEN (DE); Siegmund Maier, AIGLSBACH (DE); Heinrich Wachinger, KIRCHDORF (DE)

(21) Appl. No.: 17/587,749

(22) Filed: Jan. 28, 2022

Related U.S. Application Data
(60) Provisional application No. 63/254,599, filed on Oct. 12, 2021.

(51) Int. Cl. H01L 21/66; G01R 27/02; H01L 21/321; H01L 21/67

(52) U.S. Cl. CPC H01L 22/14; G01R 27/02; H01L 21/321; H01L 21/67167

(57) ABSTRACT

An integrated circuit (IC) fabrication tool and associated method for facilitating inline contactless sheet resistance measurement. In one arrangement, the tool comprises at least one main chamber, one or more processing chambers detachably coupled to the main chamber, each of the one or more processing chambers configured for effectuating a respective processing operation on a semiconductor wafer, and at least one sensor chamber detachably coupled to the at least one main chamber, the at least one sensor chamber having a contactless sensor assembly for sensing sheet resistance of a process layer of the semiconductor wafer based on eddy currents generated in the process layer.

### PRIORITY AND CROSS-REFERENCE TO RELATED APPLICATION(S)

This application claims the benefit of and priority to United States provisional patent application “INLINE CONTACTLESS SHEET RESISTANCE SENSOR CHAMBER”, Application No. 63/254,599, filed Oct. 12, 2021, in the name of Sebastian Meier et al., which is hereby incorporated herein by reference in its entirety.

### FIELD OF THE DISCLOSURE

Disclosed implementations relate generally to the field of semiconductor fabrication. More particularly, but not exclusively, the disclosed implementations relate to an inline contactless wafer metrology chamber and associated method operative in an integrated circuit (IC) fabrication flow.

### BACKGROUND

Within the semiconductor industry, there is a constant demand for integrated circuits (ICs) that exhibit higher performance at a lower cost. In order to design and manufacture high performance ICs cost-effectively, several parameters of the manufacturing process need to be monitored and carefully controlled. For example, film properties, linewidths, and defect levels need to be measured, first to optimize the manufacturing process, and then subsequently to ensure that it is operating under control.

Wafer metrology tools are used to design and manufacture ICs by carefully controlling film properties, linewidths, and potential defect levels in order to optimize the manufacturing process of high performance devices. Metrology tools may be combined with wafer inspection capabilities so as to ensure that appropriate physical and electrical properties of semiconductor devices under production are maintained. Whereas cost-effective wafer metrology is a necessity in modern semiconductor IC fabrication, inspecting and monitoring wafers is not without associated costs. Example costs may typically include capital outlays for the inspection/metrology equipment as well as manufacturing costs such as, e.g., time spent on inspection itself, which slows down wafer throughput; establishment of separate metrology stations for performing measurements, verifying results and dispositioning wafer lots; and the like. A primary goal of wafer metrology is to improve fab operations for overall higher yields, ensuring that flawed lots never make it to final test (e.g., to facilitate early interdiction) and that, when possible, flawed wafers can be reworked.

Whereas advances in wafer metrology systems and associated methods continue to grow apace, several lacunae remain, thereby requiring further innovation as will be set forth hereinbelow.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to an IC fabrication tool and associated method for facilitating inline contactless metrology operations with respect to one or more conductive or semiconductive process layers of a wafer, e.g., for measuring sheet resistance, thickness, etc. associated with the process layers. In one arrangement, an example fabrication tool may comprise at least one main chamber, one or more processing chambers coupled to the main chamber, each of the one or more processing chambers configured for effectuating a respective processing operation on a semiconductor wafer, and at least one sensor chamber coupled to the at least one main chamber, the at least one sensor chamber including a contactless sensor assembly for sensing sheet resistance of a process layer of the semiconductor wafer based on eddy currents generated in the process layer. In some examples, the processing chambers and/or sensor chambers may be detachably and/or sealably mounted to the at least one main chamber so as to maintain and/or ensure the integrity of the processing conditions of a fabrication flow.

In another example, a method of fabricating an IC is disclosed. The method comprises, inter alia, processing a semiconductor wafer in a fabrication flow having a sequence of process steps for creating at least one semiconductor die containing the IC, the semiconductor wafer forming a substrate for the IC, wherein the sequence of process stages may include at least one operation performed in a processing chamber of a fabrication tool with respect to a process layer of the semiconductor wafer. The example method may include performing a sheet resistance measurement of the process layer using a contactless sensor assembly disposed in a sensor chamber integrated with the fabrication tool, the contactless sensor assembly comprising an eddy current sensor assembly including at least one sensor probe operative for sensing sheet resistance of the process layer. In some arrangements, a processing operation performed using the fabrication tool may comprise effectuating at least one of a physical vapor deposition (PVD) process, a chemical vapor deposition (CVD) process and/or an atomic layer deposition (ALD) process for forming the process layer. In some arrangements, a processing operation performed using the fabrication tool may comprise a rapid thermal processing/annealing (RTP/RTA) operation for modifying the electrical properties of the process layer. In some arrangements, the fabrication tool may be configured to effectuate a doping process (e.g., ion implantation) where a substrate region's electrical properties may be modified. In some arrangements, an example process layer may be formed as a stack of conductive layers having an overall sheet resistance, wherein each conductive layer may have a corresponding sheet resistance measurement obtained by a contactless sensor assembly in a sequentially executed flow, the overall sheet resistance determined as a resultant sheet resistance based on respective sheet resistances of each conductive layer.

### BRIEF DESCRIPTION OF THE DRAWINGS

Implementations of the present disclosure are illustrated by way of example, and not by way of limitation, in the Figures of the accompanying drawings. It should be noted that different references to “an” or “one” implementation in this disclosure are not necessarily to the same implementation, and such references may mean at least one. Further, when a particular feature, structure, or characteristic is described in connection with an implementation, it is submitted that it is within the knowledge of one skilled in the art to effect such feature, structure, or characteristic in connection with other implementations whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIGS. 1 and 2 depict general schematic configurations of a wafer processing tool having at least one inline contactless sensor chamber that may be deployed in association with one or more process stages of a wafer fabrication flow according to some examples of the present disclosure;

FIGS. 3A-3C depict various views of an inline contactless sensor chamber including an eddy current sensor assembly comprising one or more sensor probes according to some examples of the present disclosure;

FIG. 4 depicts a perspective view of a housing that may be used as part of a sensor chamber according to some examples of the present disclosure;

FIG. 5 depicts a perspective view of a hub configured to hold a semiconductor process wafer in a sensor chamber according to some examples of the present disclosure;

FIG. 6 depicts a perspective view of a blade configured to support a semiconductor process wafer while being transferred using a robotic arm during a metrology operation according to some examples of the present disclosure; and

FIGS. 7A and 7B are flowcharts of representative methods according to some examples of the present disclosure.

### DETAILED DESCRIPTION

Examples of the disclosure are described with reference to the attached Figures wherein like reference numerals are generally utilized to refer to like elements. The Figures are not drawn to scale and they are provided merely to illustrate examples. Numerous specific details, relationships, and methods are set forth below to provide an understanding of one or more examples. However, it should be understood that some examples may be practiced without such specific details. In other instances, well-known subsystems, components, structures and techniques have not been shown in detail in order not to obscure the understanding of the examples. Accordingly, it will be appreciated by one skilled in the art that the examples of the present disclosure may be practiced without such specific components, structures or subsystems, etc.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

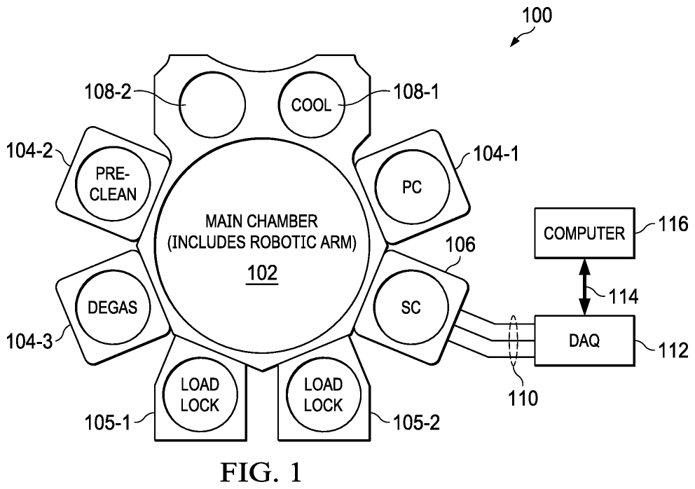

Referring to the drawings, FIG. 1 depicts a generalized schematic configuration of a wafer processing tool having at least one inline contactless sensor chamber that may be deployed in association with one or more process stages of an IC fabrication flow according to some examples of the present disclosure. By way of illustration, processing tool 100 may be implemented as a configurable tool for deployment at a process stage where it may be desirable to perform in situ metrology operations with respect to one or more structural components of a semiconductor wafer in a contactless manner. Depending on implementation, a semiconductor manufacturing process may include a fabrication flow involving one or more thin-film and/or thick-film processing/deposition stages, rapid thermal processing (RTP) and rapid thermal annealing (RTA) stages used for dopant activation, metal reflow, surface/interface conditioning of grown layers or implanted substrate regions and the like, chemical-mechanical polishing (CMP) stages, etc. Further, deposition processing stages may be based on various technologies and may be deployed for fabricating single and/or multi-layer structures comprising known or heretofore unknown conductive or semiconductive materials. In general, various properties and characteristics such as film thicknesses, sheet resistances, temperature-dependency of resistances, etc., may need to be monitored and controlled during such processing stages in spite of the harsh ambient conditions that may be present therein. Accordingly, some example implementations of processing tool 100 may be configured to integrate appropriate sensors in a tooling system that may be operative in hostile environments, e.g., high temperatures, plasmas, high and/or ultra high vacuum (HV/UHV) conditions, etc., as will be set forth in further detail below.

In some arrangements, processing tool 100 may be configured as a multifunctional tooling system adapted to effectuate various process steps, operations and/or recipes associated with a broad range of wafer fabrication technologies including but not limited to physical vapor deposition (PVD), chemical vapor deposition (CVD) including atomic layer deposition (ALD) and plasma enhanced CVD (PECVD), etc. as well as RTP/RTA processes, which may be deployed during early stages, middle stages, or late stages of a frond-end-of-line (FEOL) and/or a back-end-of-line (BEOL) portion of an IC fabrication flow. Without limitation, an implementation of processing tool 100 as a deposition tool having one or more sensor chambers configured to facilitate in situ wafer metrology using contactless sensing technology based on eddy current sensing is set forth in particular detail herein for purposes of some examples of the present disclosure.

In one arrangement, processing tool 100 may comprise at least one main chamber 102 and one or more processing chambers (PCs) detachably coupled to the at least one main chamber 102, wherein each of the PCs may be configured for effectuating a respective processing operation on a semiconductor wafer (also referred to as a semiconductor process wafer or simply a process wafer or wafer in some examples) according to one or more process recipes depending on the particular processing stage of a fabrication flow where the tool 100 is deployed. By way of illustration, chambers 104-1 to 104-3 exemplify a plurality of PCs that may be configured to effectuate CVD/PVD/ALD operations as well as other related processing operations such as, e.g., degas, RF or plasma pre-clean, etc. At least one sensor chamber (SC) 106 may be detachably coupled to main chamber 102, wherein sensor chamber 106 may include a contactless sensor assembly comprising one or more eddy current sensor probes for sensing the sheet resistance of a process layer of the semiconductor wafer in some examples. In some arrangements, additional bays, chambers or compartments may also be provided in association with main chamber 102 for facilitating other related processing steps, e.g., wafer cool down, additional pre-cleaning (dry and/or wet pre-clean), etc., as exemplified by chambers 108-1 and 108-2. Further, one or more load lock chambers 105-1 and 105-2 may be provided in association with main chamber 102 for facilitating loading, unloading, and/or storage of wafers, wherein load lock chambers 105-1/105-2 may be configured for transferring a group of process wafers between main chamber 102 and an external stage, e.g., by way of a wafer cassette apparatus (not specifically shown in this FIG.) in wafer ingress or egress operations. In some arrangements, main chamber 102 may be configured to house, contain or otherwise enclose a robotic wafer handler (not specifically shown in this FIG.) for transferring the semiconductor wafers (either individually or in groups) between two chambers, e.g., between a load lock chamber and a processing chamber, between a processing chamber and a sensor chamber, or between two processing chambers, etc., according to a particular process recipe flow, which may include one or more inline wafer metrology operations performed in situ in one or more sensor chambers in example implementations.

Depending on implementation and/or process flow requirements, processing chambers 104-1 to 104-3, load lock chambers 105-1/105-2, sensor chamber(s) 106, additional/expansion chambers 108-1/108-2, as well as main chamber 102 may be (de)pressurized to varying levels using appropriate gases (e.g., Argon, Nitrogen, etc.) and/or air in conjunction with one or more servomechanical vacuum pumps and associated hardware (e.g., cryo pumps, turbo pumps, rotary vane pumps, etc., not specifically shown in this FIG.). Suitable mechanical coupling between main chamber 102 and other chambers (e.g., PCs and SCs) may therefore be provided in order to facilitate chamber detachability as well as vacuum integrity during operation. In some examples, base pressures of deposition process chambers 104-1 and sensor chamber(s) 106 may be about 10⁻⁹-10⁻⁶ Torr (about 10⁻⁷-10⁻⁴ Pa). In some examples, base pressures of main chamber 102 may be about 10⁻⁸-10⁻⁶ Torr (about 10⁻⁶-10⁻⁴ Pa). In some examples, base pressures of pre-clean chambers 104-2 may be about 10⁻⁷-10⁻⁶ Torr (about 10⁻⁵-10⁻⁴ Pa). In some examples, base pressures of load lock chambers 105-1/105-2 may be about 10⁻⁶-10⁻⁵ Torr (about 10⁻⁴-10⁻³ Pa). Because of the vacuum requirements and other harsh processing conditions, processing chambers 104-1 to 104-3, load lock chambers 105-1/105-2, sensor chamber(s) 106, additional/expansion chambers 108-1/108-2 as well as main chamber 102 may be constructed in some arrangements using vacuum-compatible/compliant materials that can withstand the operating conditions of a process flow, e.g., steel, aluminum, hard transparent/translucent materials such as acrylic glass, plastics and ceramics, etc.

In one arrangement, an electrical interface 110 may be provided with sensor chamber 106 for applying and/or gathering signals to and/or from the sensor probes disposed therein for purposes of effectuating metrology operations using eddy current sensing (ECS) technology. For example, electrical interface 110 may be coupled to a data acquisition (DAQ) unit 112 for collecting sensor data and transmitting the data to a host computer 116 using any known or heretofore unknown data collection/transmission protocols in conjunction with suitable wireless and/or wireline and/or optical communications technologies and infrastructures, generally exemplified by interface 114. In some implementations, measurement signals and/or data signals from sensor chamber 106 may be processed for generating suitable reports, notifications/alarms, and the like (generally referred to as “actionable process intelligence”) regarding the properties of one or more process layers of the semiconductor process wafers fabricated using processing tool 100. Depending on implementation, host computer 116 may be deployed as a local or remote host, or at a cloud-based data center associated with an IC fabrication facility, which may include one or more processors operating under program control to effectuate sensing processes and ECS algorithms, data analysis, report generation, etc.

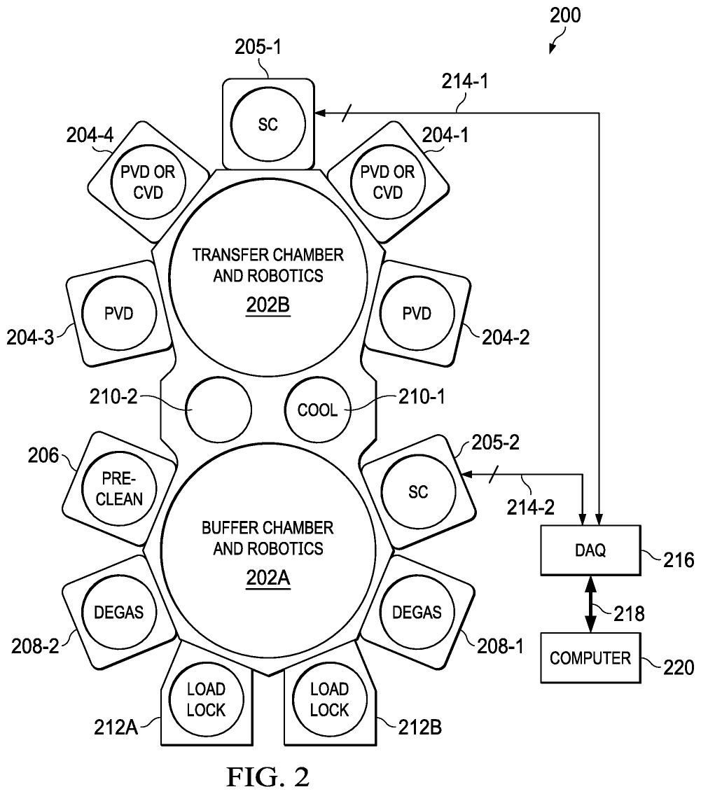

In some arrangements, an IC fabrication tool system having contactless in situ metrology capability may be implemented as a (re)configurable apparatus having multiple main chambers, wherein each main chamber may be provided with one or more processing chambers, at least one main chamber integrated with one or more sensor chambers in addition to the processing chambers, e.g., as a further expansion of processing tool 100, according to some examples herein. FIG. 2 depicts a generalized schematic configuration of a wafer/IC processing tool 200 having two main chambers 202A, 202B, wherein each main chamber may be provided with various processing chambers and one or more sensor chambers. In one implementation, main chamber 202A may be configured as a buffer chamber having robotic wafer handling capability for facilitating loading and/or unloading of semiconductor process wafers using load lock chambers 212A and 212B. Main chamber 202B may be configured as a transfer chamber that may also include a robotic wafer handling system for facilitating the transfer of wafers from one chamber to another depending on the process flow. In some examples, robotic wafer handling systems may comprise a robotic arm operative to rotate around vertical and horizontal axes as well as travel on any plane in a 3D space enclosed by main chambers 202A/202B.

Regardless of whether configured as a buffer chamber or a transfer chamber, main chambers 202A and 202B may each be generally implemented as main chamber 102 described in detail above at least for purposes of some examples of the present disclosure. Accordingly, various processing chambers such as, e.g., PVD and/or CVD chambers 204-1 to 204-4, pre-clean chambers 206, degas chambers 208-1 208-2, cooling chambers 210-1, 210-2, etc., may be detachably coupled to chambers 202A/202B in different configurations, which are generally representative of processing chambers 104-1 to 104-3 and cooling chambers 108-1, 108-2 previously set forth in reference to FIG. 1, the description of which is equally applicable herein, mutatis mutandis. Further, one or more processing chambers, e.g., cool-down chambers 210-1, 210-2, may be operative in some arrangements as passage chambers disposed between main chambers 202A/202B for allowing the transfer of one or more semiconductor wafers therebetween. Accordingly, a first portion of the one or more processing chambers may be coupled to a first main chamber, e.g., buffer chamber 202A, whereas a second portion of the one or more processing chambers may be coupled to a second main chamber, e.g., transfer chamber 202B, with one or more chambers or conduits operative as a passage disposed between buffer and transfer chambers 202A/202B in some configurations.

In one arrangement, transfer chamber 202B and/or buffer chamber 202A may each be integrated with one or more sensor chambers 205-1, 205-2, wherein each sensor chamber may include one or more eddy current sensor probes for facilitating contactless wafer metrology as previously mentioned. In one arrangement, each sensor chamber may have respective wired/wireless interfaces 214-1, 214-2 to one or more DAQ units 216 for transmitting and receiving signals with respect to the operation of the sensor probes. As previously set forth, collected data/sense signals may be processed by a host computer 220 for providing the actionable measurement information with respect to the wafer parametrics monitored in an example process flow. Some example implementations may involve not only real-time error detection but also engaging in or causing suitable corrective action such as interdiction or interruption of processing by the fabrication tool for facilitating management decisions (e.g., wafer rework, scrap, etc.).

Depending on implementation, various types and/or configurations of sensor probes based on ECS technologies may be integrated in an example sensor chamber of a process tool of the present disclosure for facilitating direct and/or indirect measurements of a number of characteristics of one or more conductive layers/regions of a process wafer. For example, parameters such as sheet resistance, resistivity, film thickness, temperature dependency/variability of the sheet resistance, etc., may be measured and analyzed at various stages of a process flow using appropriate sensor probes. In an example operation involving a single-element ECS probe, a coil of conductive wire may be excited with an alternating electrical current at a given frequency, which is operative to generate an alternating magnetic field around itself, that oscillates at the same frequency as the electrical current flowing through the coil. When the probe is placed near the conductive process layer of a semiconductor wafer, electrical currents(i.e., eddy currents) flowing in a direction opposite to the direction of the currents in the coil are induced in the process layer. The characteristics of the eddy currents are determined by the characteristics of the process layer and its composition. For example, variations in the electrical conductivity and magnetic permeability of the conductive process layer (and potentially the presence of any potential defects therein) can cause a secondary magnetic field generated by the eddy currents, which may be detected or otherwise sensed by the impedance changes in the coil. The resulting signals may be processed and analyzed using suitable algorithms to determine and/or compute the relevant parameters of the process layer, e.g., sheet resistance, thickness, etc. In some arrangements involving two separate coils, a primary magnetic field may be generated when an AC signal is applied to a first coil element, referred to as an induction coil, excitation coil, force coil, or in terms of similar import in some examples. The primary magnetic field is operative to cause eddy currents in a conductive process layer when the probe containing the primary coil is placed in the vicinity of the semiconductor process wafer including conductive process layer or region of interest. As in the single-element arrangement, a secondary magnetic field may be generated by the eddy currents in the opposite direction to that of the primary magnetic field. Instead of using the same coil for sensing the secondary magnetic field, a second element, referred to as a pick up coil or a sense coil in some examples, may be used for detecting the secondary magnetic field that is dependent upon the characteristics of the process layer. Depending on implementation, therefore, an ECS arrangement may comprise a single sensor probe having a single element for both induction/excitation and detection/sensing, or a pair of probes that each have a respective element for induction/excitation and detection/sensing, or any combination thereof.

Further, some example ECS arrangements may include single-sided and/or double-sided configurations of probe placement relative to a sample, e.g., a semiconductor process wafer, depending on measurement modality being implemented. In reflection mode, one or more sensor probes may be placed relative to one side of the process wafer, e.g., over the frontside of the wafer or underneath the backside of the wafer that is horizontally disposed in a sensor chamber, in a single-sided setup configuration wherein the sensor probes may be configured for excitation and/or detection. In transmission mode, a double-sided setup configuration involves positioning one or more induction/excitation probes on one side of the process wafer whereas a corresponding number of detection/sensing probes are positioned on the opposite side of the process wafer. In some arrangements, induction/excitation probes may include inductive coil elements whereas detection/sensing probes may include not only inductive coils but other elements as well such as, e.g., Hall sensors, fluxgate sensors, giant magnetoresistance (GMR) sensors, superconducting quantum interference device (SQUID) sensors, etc. In some arrangements, example ECS configurations may involve using sensor probes operating in a broad range of frequencies. For example, characterization of process layers comprised of materials expected to have low sheet resistance may need lower frequencies whereas higher frequencies may be used for characterizing process layers fabricated from materials having high sheet resistance.

It will therefore be recognized that an example sensor chamber integrated in an IC fabrication tool may be configured with various permutations and/or combinations of ECS probe arrangements depending on implementation, e.g., based on fabrication deployment requirements, process layers of the wafers to be characterized, etc. Furthermore, it will be seen that example implementations may be configured without using a chuck in a sensor chamber for supporting a process wafer for metrology purposes. In some baseline chambers, a chuck may, for example, be formed of metallic/conductive materials, ceramics encasing an electrode, etc., which can cause interference with the magnetic fields used/caused in ECS arrangements. As the placement of a chuck in the sensor chamber and/or the materials used for manufacturing the chuck may impede, prevent or otherwise thwart incorporating ECS-based probes (e.g., due to electric/magnetic interference, spatial intrusion, etc.), example implementations may be advantageously configured to present process wafers in a “chuckless” environment. Without limitation, set forth below is a description of an inline contactless sheet resistance sensor chamber, also referred to as a wafer metrology chamber, including an eddy current sensor assembly that comprises a double-sided transmission mode sensor probe arrangement according to some examples of the present disclosure. In some example implementations, ECS sensor probes manufactured by SURAGUS GmbH, Maria-Reiche-Straße 1, 01109 Dresden, Germany, may be incorporated into a custom sensor chamber that may be integrated within a fabrication tool according to the teachings herein although sensors from other sources may also be used according to some additional and/or alternative implementations of the present disclosure.

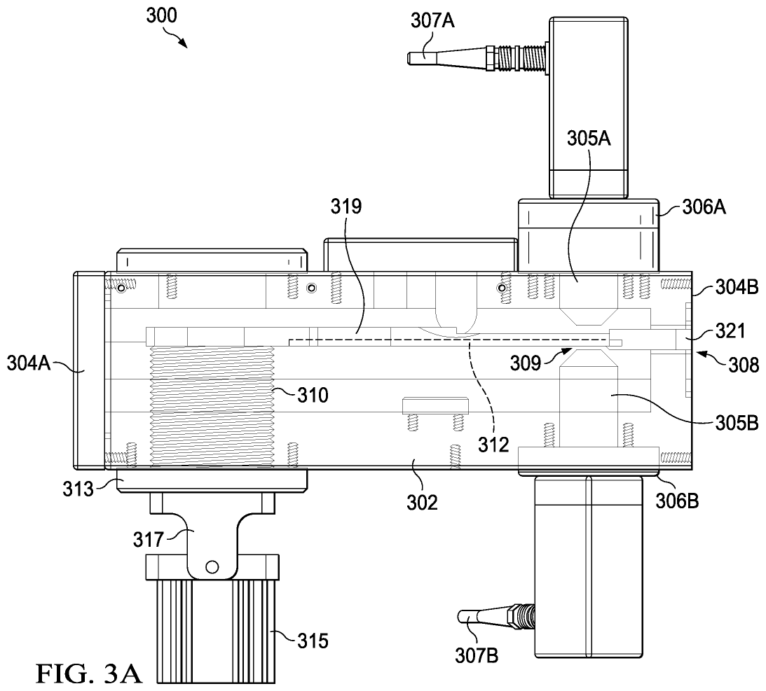

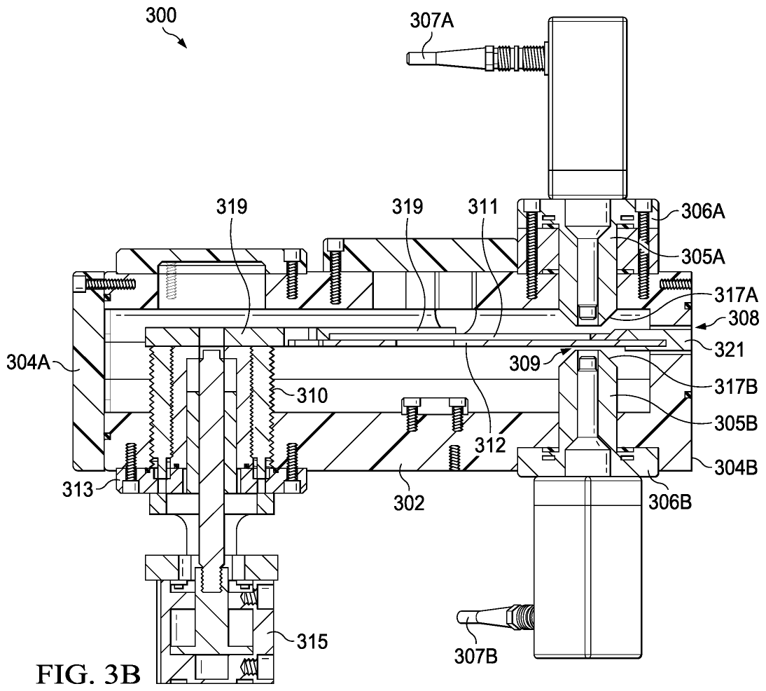

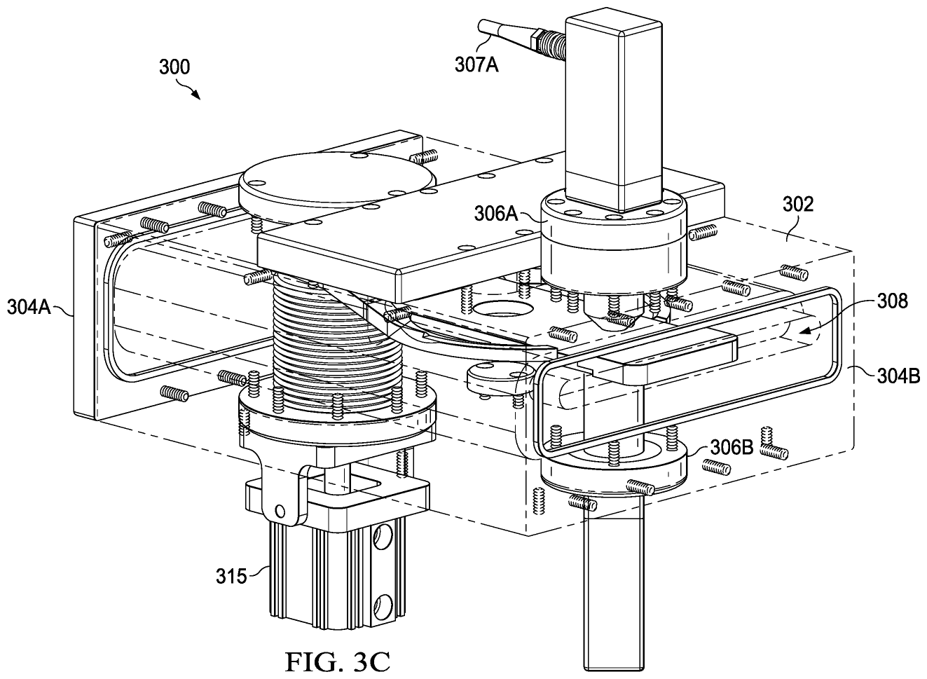

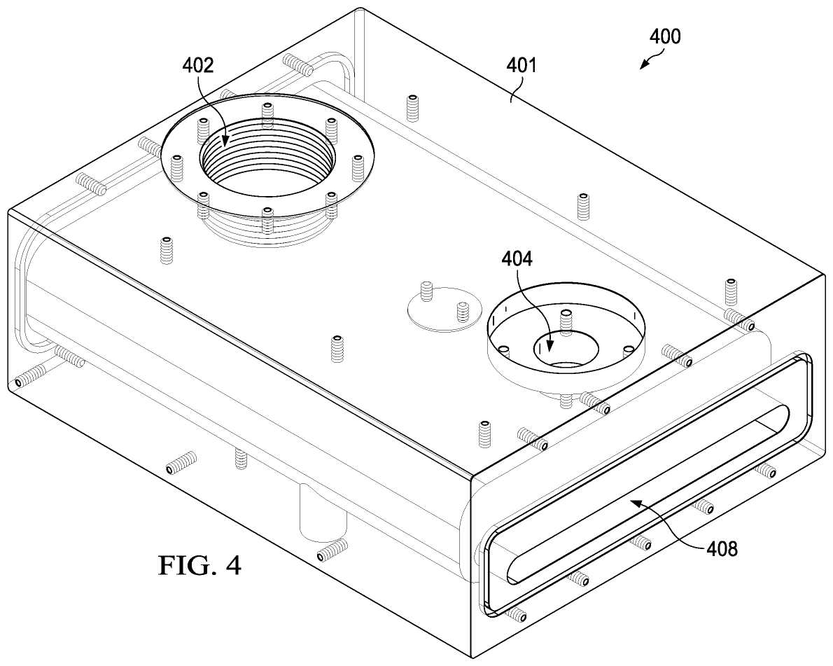

FIGS. 3A-3C depict various views of an inline contactless sensor chamber 300, wherein a housing 302 having a sealed terminus 304A and an attachment terminus 304B may be provided for accommodating a semiconductor process wafer under measurement in a controlled vacuum environment in which one or more ECS probes 305A, 305B may be partially disposed according to some examples of the present disclosure. FIG. 3A illustrates a side elevation view of sensor chamber 300, FIG. 3B illustrates a partially exposed side elevation view of sensor chamber 300 wherein some internal components are illustrated in a cross-sectional view, and FIG. 3C illustrates a 3D perspective view of sensor chamber 300. As previously noted, housing 302 may be made of materials that can withstand the harsh operating conditions that may be encountered during certain stages of an IC fabrication flow. Further, at least some portions of housing 302 may be constructed in some arrangements using shatter-resistant transparent/translucent material (e.g., ballistic glass) in order to provide some visibility into the space enclosed by housing 302. Generally, housing 302 may be configured as any suitable enclosure having a form factor amenable for integration with industry-standard and/or custom-designed IC fabrication tooling systems. In some arrangements, attachment terminus 304B may be configured to sealably attach to at least one main chamber of a tooling system such as, e.g., processing tools 100 or 200 described above, wherein attachment terminus 304B may be provided with an ingress/egress opening 308 for facilitating the transfer of a semiconductor wafer of varying sizes (e.g., up to or beyond 300 mm) between the at least one main chamber of a processing tool and housing 302 of sensor chamber 300 integrated therewith. In some arrangements, housing 302 may be provided with one or more apertures for facilitating sealable mounting of one or more sensor probes that may be at least partially inserted into the space enclosed by housing 302. As illustrated, sensor probes 305A, 305B may each be disposed in a respective enclosure 306A, 306B, which may be configured with suitable attachment features for facilitating coupling with housing 302 via corresponding apertures in housing 302. Whereas these apertures are not specifically shown in FIGS. 3A-3C, an example housing 400 shown in FIG. 4 illustrates an aperture 404 provided in a housing body 401 that may be co-axially aligned with another aperture on the opposite side of housing body 401 for facilitating sealable mounting of sensor probes in some arrangements particularly with respect to effectuating transmission mode sensing operations. As such, sensor probe enclosures 306A, 306B and the apertures of housing 302 for accepting sensor probes may be provided with various types of attachment features for facilitating sealable mating therebetween while maintaining vacuum/pressure integrity of sensor chamber 300 during operation (e.g., O-rings, seals, gaskets, washers, etc. that may be securely held in place using mechanical features such as flanges, brackets, clasps, clamps, compression fittings and the like).

In some arrangements, each sensor probe enclosure 306A, 306B may be provided with suitable vacuum-compliant tubing/piping 307A, 307B for supporting various electrical/mechanical/pneumatic interfacing components, e.g., electrical cable connectors, hoses, conduits, etc.) that may be coupled to appropriate electrical and mechanical hardware (not specifically shown in FIGS. 3A-3C). In some arrangements, sensor probe enclosures 306A, 306B containing probes 305A, 305B may be mounted proximate to attachment terminus 304B, wherein probes 305A, 305B may be partially introduced into the space enclosed by housing 302 as previously noted. In some arrangements, sensor probes 305A, 305B may be vertically aligned, with a gap 309 disposed therebetween that is generally on the same level as opening 308 provided at attachment terminus 304B.

In some arrangements, a lift assembly 310 may be disposed in housing 302, for example, located proximate to sealed terminus 304A, wherein lift assembly 310 may be coupled to a wafer holder component operative to receive, accept and/or hold a process wafer transferred into housing 302 via opening 308 from a main chamber for performing metrological operations. In some arrangements, lift assembly 310 may be at least partially disposed in housing 302 facilitated by one or more suitably sized apertures (not specifically shown in FIGS. 3A-3C), wherein appropriate coupling arrangements 313 may be provided for sealably mounting lift assembly 310 to housing 302. In representative housing arrangement 400 illustrated in FIG. 4, aperture 402 distally disposed from wafer ingress/egress opening 408 exemplifies an orifice that may be sized for mounting coupling mechanism 313 to an example housing of a sensor chamber. In some arrangements, coupling mechanism 313 may be supported by a pedestal or platform 317 coupled to a columnar member 315. As with sensor probe aperture(s) 404, orifice 402 and housing body 401 may be provided with various types of attachment features for facilitating sealable mounting therebetween while maintaining vacuum/pressure integrity of sensor chamber 300 during operation when implemented as part of housing 302 thereof.

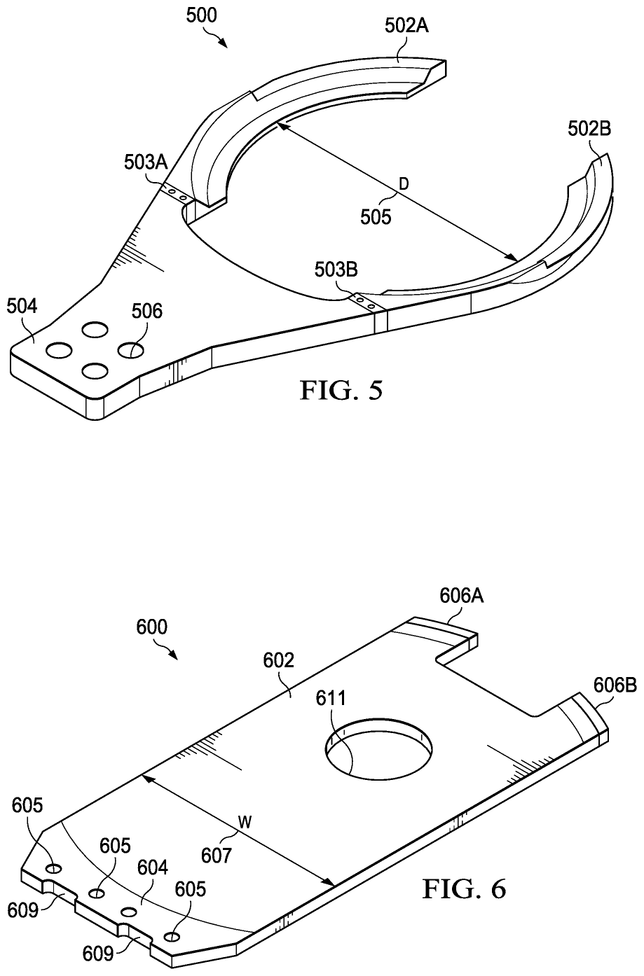

In some arrangements, lift assembly 310 may be operated by pneumatic/hydraulic systems (e.g., bellows, pumps, etc.) for actuating a vertical movement of lift assembly 310 in controllable manner. A hub component 319 coupled to lift assembly 310 may be operative as a wafer holding component, wherein hub 319 may be provided with a pair of opposing arms (e.g., in a fork-like arrangement, not specifically shown in FIGS. 3A-3C) configured to hold, clasp, grasp or otherwise embrace a semiconductor wafer 311 when transferred into housing 302 from a main chamber. FIG. 5 depicts a perspective view of a hub component 500 configured to hold a semiconductor process wafer in a sensor chamber according to some examples of the present disclosure. As illustrated in FIG. 5, an attachment portion 504 of hub 500 may be provided with a plurality of holes 506 for facilitating mechanical coupling with lift assembly 310. In some arrangements, attachment portion 504 may be integrally formed as part of a handle coupled to opposing holding members, e.g., forks or arms 502A, 502B, which may be provided as part of hub 500 as a unitary unit (e.g., constructed as a single unit). In some alternative/optional and/or additional arrangements, opposing holding members 502A, 502B may be coupled to attachment portion or handle 504 using respective hinged mechanisms 503A, 503B (e.g., spring-activated) for adjusting a spacing (D) 505 between holding members 502A, 502B. Regardless of how an example hub component 319/500 may be constructed, it is generally operative in association with lift assembly 310 for positioning the semiconductor process wafer 311 proximate to at least one sensor probe, e.g., disposed between sensor probes 305A, 305B at a configurable distance from either of sensor probes 305A/305B. In operation, opposing fork arms 502A/502B of hub 500 are configured to retain the semiconductor process wafer 311 in position for measurement without using a chuck in some example arrangements. Because no chuck comprised of conductive material is disposed in sensor chamber 300 for holding process wafer 311 during measurement operations, sensor probes 305A/305B positioned in relatively dose proximity to the conductive process layers of process wafer 311 are advantageously arranged in an in situ, in vacuo configuration for providing “clean” ECS measurement signals that are not confounded by any interference that may be caused by surrounding metallic components such as the chuck and/or any conductive components disposed in housing 302 or conductive portions thereof in inline metrological operations.

In some arrangements, a robotic wafer handling arm may be provided in a main chamber for introducing, advancing and/or retracting semiconductor process wafer 311 into and/or from sensor chamber 300. A detachable plate or blade for holding a wafer may be coupled to the robotic wafer handing arm, wherein the blade may be dimensioned so as to support the wafer as it passes through opening 308 provided at attachment terminus 304B of housing 302. An example blade 312 positioned in housing 302 is illustrated in FIGS. 3A/3B, wherein a robotic arm portion 321 to which blade 312 is coupled is partially shown. Additional details with respect to an example blade according to some implementations are shown in FIG. 6. By way of illustration, a perspective view of a blade 600 is depicted in FIG. 6, wherein blade 600 may be configured to support a semiconductor process wafer while being transferred in and/or out of a sensor chamber during a metrology operation according to some examples of the present disclosure. Blade 600 may comprise a planar platform 602 having a coupling portion 604 operative to couple to a robotic wafer handling arm, wherein coupling portion 604 may be provided with holes 605 and/or notches 609, etc., for facilitating mechanical coupling therewith. In some arrangements, platform 602 may have a width (W) 607 that is sized to be accommodated between the opposing arms of a hub, e.g., hub 500, which may be coupled to lift assembly 310. Platform 602 may be provided with arresting brackets, lips, protrusions, grooves or similar structures, as exemplified by structures 606A, 606B, at a distal end opposite to coupling portion 604 so as to facilitate secure handling of a semiconductor process wafer during transfer operations. In some arrangements, blade platform 602 may be provided with one or more apertures 611 sized for passing or otherwise facilitating transmission mode signals between one or more sensor probe pairs, e.g., sensor probes 305A/305B. In some arrangements, blade platform 602 may not include an aperture, e.g., where a reflection mode ECS arrangement is implemented. In some example implementations, blade 312 and hub/fork component 319 may therefore be constructed as having substantially flat or planar form factors, respectively, that may be dimensioned to be capable of being adjustably positioned in the proximity of a sensor assembly, e.g., relative to space 309 between sensor probes 305A/305B, wherein the shapes and/or sizes of the components may be configured in myriad ways and arrangements.

In some example arrangements, sensor probes 305A, 305B each may include a coil element (not specifically shown in FIGS. 3A-3C), which may be configured as a sender (e.g., for induction or excitation) or a receiver (e.g., for detection or sensing) depending on a particular ECS setup configuration. In some arrangements, the coil elements may be disposed within corresponding probes 305A, 305B substantially close to respective tips 317A, 317B thereof, e.g., within about 0.5 cm to 1.5 cm. During sensing operations, primary magnetic field lines and secondary magnetic filed lines (not specifically shown in FIGS. 3A-3C) are disposed generally orthogonal to the horizontal plane of semiconductor process wafer 311, with eddy currents caused in the horizontal process layer or region of interest having a particular thickness. In some example arrangements, the operating conditions of sensor probes 305A, 305B may be calibrated such that the resulting magnetic fields are not perturbed by any surrounding metallic components of sensor chamber 300 and/or robotic handler components configured to transfer semiconductor process wafer 311 in and out of housing 302.

In an example measurement operation, two line scans of semiconductor process wafer 311 may be performed after a particular processing step has been effectuated with respect to a process layer, e.g., forming the process layer by at least one of a PVD, CVD, or ALD process, or RTP/RTA process after diffusion, ion implantation, etc. In some arrangements, as process wafer 311 enters housing 302 of chamber 300 via opening 308 on a blade actuated by a robotic arm, sensor assembly comprising probes 305A/305B may be configured to rapidly recognize (e.g., <10 msec) that a wafer is entering. Appropriate excitation may be applied to one of sensor probes, wherein ECS measurement signals may be sensed by the other sensor probe configured as a detector. In one arrangement, sensor probe 305A may be configured as a sender whereas sensor probe 305B may be configured as a detector. In another arrangement, sensor probe 305B may be configured as a sender whereas sensor probe 305A may be configured as a detector. Regardless of a particular ECS configuration, example measurement operations may involve, after detecting that process wafer 311 is entering housing 302 on a robotic arm's blade, performing a first line scan that may be recorded along a linear path traversing across wafer 311 until wafer 311 comes to a halt at a designated location (generally depending on the size of process wafer 311; for example, traversing about 180 mm for a 200 mm wafer). Process wafer 311 is then lifted from the blade using hub fork arrangement 319 actuated by lift assembly 319, whereupon the blade is retracted from housing 302 of sensor chamber 300 without wafer 311. Another measurement may be initiated when process wafer 311 is held in position by hub fork arrangement 319. Whereas process wafer 311 is not in motion when the measurement is initiated at a designated location, process wafer 311 may be in a cooling phase due to normal thermal radiation. In an example arrangement, the cooling down process may be detected by ECS assembly 315A/315B because the process layer of interest (e.g., a deposited metal layer or an RTP/RTA activated region in silicon) has a specific Temperature Coefficient of Resistance (TCR), which causes the resistance to be dependent on temperature. As the temperature of a material decays asymptotically to ambient temperature over time, the measurement signals associated with the process layer may exhibit a characteristic functional relationship depending on how long process wafer 311 is in housing 302 (e.g., which may vary from a few seconds up to several minutes (5-10 minutes) or even longer) that may be captured in a data acquisition unit. After a specific time period has elapsed, process wafer 311 may be retracted from housing 302 on the robotic arm's blade. As process wafer 311 is in motion while leaving housing 302, a second line scan across process wafer 311 may be conducted in some example arrangements. Data collected over the two scans as well as the time-dependent TCR functional relationship data may be processed using suitable algorithms executed by a computer for determining sheet resistance of the process layer. Additionally, the thickness and temperature of the process layer may also be computed or otherwise determined from the sheet resistance computations based on known relationships involving these parameters. Where multiple process layers are involved, e.g., a multi-layer metal stack, measurement operations may be conducted after each layer is deposited, whereby individual process layers may be monitored to ensure that they are in compliance with respective fabrication specifications. Further, sheet resistance of the overall metal stack may be computed based on known relationships involving parallel resistances. In still further arrangements, an independent temperature sensor (e.g., a thermocouple) may be integrated with a chamber component, e.g., a hub component, for obtaining direct temperature measurements relative to the process wafer independent of the indirect temperature values calculated from sheet resistance measurements.

In some implementations where the cooling rate of a process wafer is not independent of environmental variables that cannot be controlled, a reliable estimate of the temperature of the process wafer may not be extracted by ECS measurements alone. An example arrangement may therefore involve an independent temperature metrology process in additional, optional and/or alternative variations, as noted above. In one example implementation, an infrared window may be provided as part of housing 302, wherein a temperature sensor may be provided for thermal sensing operations with respect to a process wafer. In some implementations, a thermal shield may be provided to shied a sensor chamber from external IR radiation such that direct in situ temperature measurements are not affected thereby. Where a thermal sensor is installed in association with a hub or fork lift component, a thermocouple of low mass may be configured for achieving fast response times in measurement operations.

Although a single pair of sensor probes 305A/305B disposed on the opposite sides of process wafer 311 are described above, it will be recognized that multiple pairs of sensor probes may be deployed in some arrangements where each pair may be configured to operate in transmission mode such that one sensor probe of a pair may be disposed on one side of a process wafer while the other sensor probe of the pair may be disposed on the other side of the process wafer. In such arrangements, different line scan operations may be performed across a process wafer. Still further different types of scanning operations may be performed in other ECS arrangements depending on, e.g., whether single or multiple sensor probes are deployed on the same side of a process wafer (for instance in reflection mode). As such, example sensor chamber arrangements having suitable ECS probe configurations may be implemented for metrological operations relative to thin films as well as thick films in addition to multi-layer film stacks and buried layers. By way of example, a nonexhaustive group of materials that may be used in forming process layers or regions in semiconductor wafers that can be monitored in some representative implementations of the present disclosure are: Ti, TiN, Al, AlN, TiAl, Al+Cu, Cu, NiCrAl, SiCr, NiCr, TiW, W, Pt, Vd, Co, Nb, Fe, TaN, Ta, Pd, Au, as well as metal alloys like piezoelectric ceramic materials (PZTs), semiconductor materials such as, e.g., Si, Ge, GaAs, SiC, other Group III-V materials, polysilicon, doped Si (e.g., before and after activation), and the like. Because example sensor chambers having a suitable ECS probe configuration may be integrated with PVD/CVD/ALD tools, ion implantation/doping chambers and/or RTP/RTA tools wherein inline measurements may be effectuated without taking the tools offline for qualification, a representative arrangement of the present disclosure may involve implementing a self-qualifying process tool having an integrated in situ metrology capability in accordance with the teachings herein.

An example process flow using a process tool having an integrated sensor chamber may involve some of the following operations in some arrangements. After a group of process wafers disposed in a wafer cassette are loaded into an ingress load lock chamber of the process tool, a robotic wafer handler disposed in a main chamber may individually transfer the process wafers into one or more processing chambers using a blade arrangement. For example, a process wafer may be introduced into a degas chamber for performing a degas operation according to a process recipe. The process wafer may then be transferred to a pre-clean/etch chamber for removing any chemical and particle impurities without altering or damaging the wafer surface or substrate. In some example implementations, the process wafer may be transferred to a PVD/CVD/ALD chamber for depositing or sputtering appropriate conductive material. After deposition, the process layer may be transferred to a sensor chamber for effectuating metrological operations such as sheet resistance measurements, temperature and thickness determinations, etc. In some example implementations where multiple depositions of conductive materials are performed, separate metrological operations may be effectuated after each deposition. In still further arrangements, a measurement operation may be conducted even before a first deposition is done because a wafer substrate (e.g., silicon) itself can be conductive, and it may be desirable to “calibrate out” the substrate's base resistivity/sheet resistance. In arrangements involving multiple conductive layers, a total sheet resistance (Rs_tot) may be determined as:

1/Rs_tot=1/Rs_subtrate+1/Rs_layer1+1/Rs_layer2+. . .

wherein a sheet resistance measurement operation may be conducted before each addition of a conductive layer.

In some example implementations, after the various measurements and/or parametric determinations are verified, the process wafer may be transferred to a cool-down chamber having an inert gas, e.g., Argon. Responsive to determining that the process wafer has reached a desired temperature, it may be transferred to the main chamber (e.g., a buffer chamber) by the robotic wafer handier, which may then be activated to place the process wafer in a wafer cassette that may be loaded into an egress/exit load lock chamber for retrieval and subsequent processing.

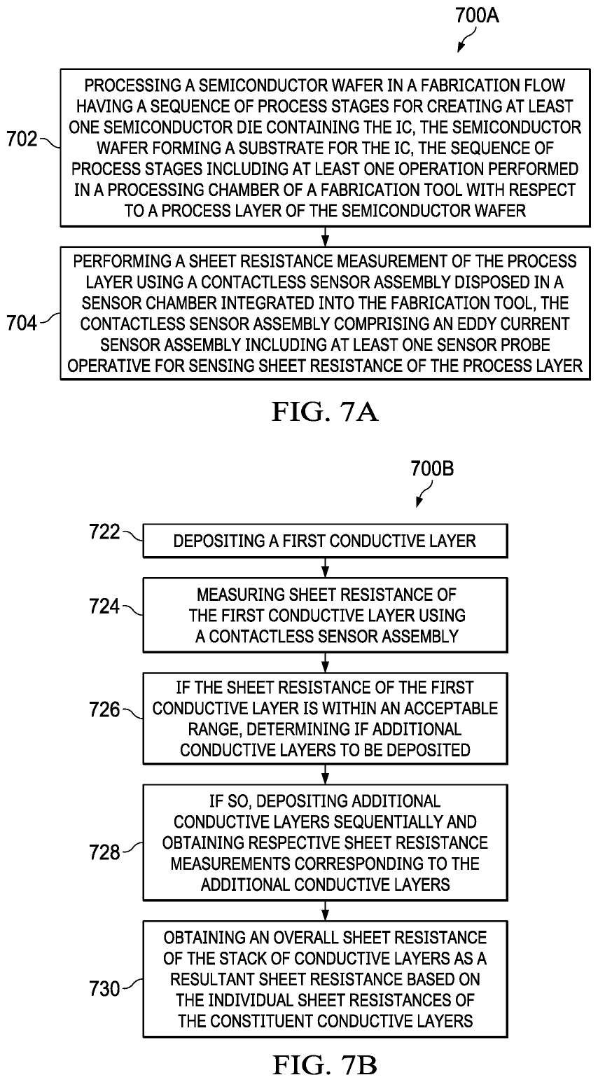

FIGS. 7A and 7B are flowcharts of representative methods according to some examples of the present disclosure, wherein various acts, steps, functions, components or blocks illustrated in the flowcharts may be (re)combined in some arrangements. Process 700A exemplifies a method of IC fabrication including inline metrological operations that may be performed in some arrangements. At block 702, a semiconductor wafer may be processed in a fabrication flow having a sequence of process stages for creating at least one semiconductor die containing an IC, wherein the semiconductor wafer may comprise a substrate for the IC. Depending on implementation, the sequence of process stages may include at least one operation performed in a processing chamber of a fabrication tool with respect to a process layer of the semiconductor wafer. At block 704, a sheet resistance measurement of the process layer may be performed using a sensor assembly disposed in a sensor chamber integrated into the fabrication tool, wherein the contactless sensor assembly comprises an eddy current sensor assembly including at least one sensor probe operative for sensing sheet resistance of the process layer without contacting the wafer. As noted previously, the semiconductor wafer may be disposed the sensor chamber without a chuck while performing measurements (e.g., chuckless measurement operations).

Process 700B is illustrative of a metrological flow for characterizing multi-layer stack structures in an in situ environment. At block 722, a first conductive layer may be deposited over or formed in a semiconductor process wafer. At block 724, sheet resistance of the first conductive layer may be measured using a contactless sensor assembly. If the sheet resistance of the first conductive layer is within an acceptable range, a determination may be made whether additional conductive layers are to be deposited, as set forth at block 726. If so, additional conductive layers may be deposited in a sequential manner, with intervening measurement operations performed after each additional layer is deposited in order to obtain respective sheet resistances corresponding thereto (block 728). An overall sheet resistance of the multi-layer stack may be obtained as a resultant sheet resistance based on the individual sheet resistances of the constituent conductive layers as set forth at block 730.

In some example arrangements where real-time interdiction based on actionable process intelligence is implemented, the foregoing processes may be modified so as to be able to “tune” the thickness of a layer being deposited. For example, if it is determined that the sheet resistance of a metal layer is X% lower than expected, the deposition time for that metal layer may be reduced by a suitable percentage or fraction as well. In such arrangements, a process feedback control loop may be implemented involving the ECS output and a process recipe management control system executed by a host computer (e.g., computer 116 shown in FIG. 1 or computer 220 shown in FIG. 2).

Based on the foregoing, it should be appreciated that examples of the present disclosure involving contactless metrology may be advantageously configured to provide reliable measurements without impact due to inhomogeneous contact quality, without damaging the surface of the process layers, or causing artifacts due to contacting. Further, some examples may also be configured for the application in process flows that may require accurate measurements of buried or encapsulated layers, which preclude contacting in some implementations. By applying contactless metrology, examples herein advantageously obviate the need for parts that undergo normal wear, e.g., probes, needles or tips, etc., which typically causes high replacement costs in common 4-probe measurement systems such as Kelvin testing systems. Additionally, because of the in situ metrological capability integrated within a process tool, an example apparatus of the present disclosure may be configured as a self-qualifying IC fabrication tool that may be qualified using production wafers without having to separately qualify the fabrication tool in an offline qualification process using test wafers. Examples of the present disclosure may therefore be deployed to help increase productivity of a fabrication facility by eliminating or reducing wafer wastage, lowering pilot costs and manpower costs, reducing downtime, etc., as well as by improving and/or recycling loop utilization.

At least some examples are described herein with reference to one or more circuit diagrams/schematics, block diagrams and/or flowchart illustrations. It is understood that such diagrams and/or flowchart illustrations, and combinations of blocks in the block diagrams and/or flowchart illustrations, can be implemented by any appropriate circuitry configured to achieve the desired functionalities. Accordingly, examples of the present disclosure may be embodied in hardware and/or in software (including firmware, resident software, micro-code, etc.) operating in conjunction with suitable processing units or microcontrollers, which may collectively be referred to as “circuitry,” “a module” or variants thereof. An example processing unit or a module may include, by way of illustration, a general purpose processor, a special purpose processor, a conventional processor, a digital signal processor (DSP), an image processing engine or unit, a plurality of microprocessors, one or more microprocessors in association with a DSP core, a controller, a microcontroller, Application Specific Integrated Circuits (ASICs), Field Programmable Gate Array (FPGA) circuits, any other type of integrated circuit (IC), and/or a state machine, as well as programmable system devices (PSDs) employing system-on-chip (SoC) architectures that combine memory functions with programmable logic on a chip that is designed to work with a standard microcontroller. Example memory modules or storage circuitry may include volatile and/or non-volatile memories such as, e.g., random access memory (RAM), electrically erasable/programmable read-only memories (EEPROMs) or UV-EPROMS, one-time programmable (OTP) memories, Flash memories, static RAM (SRAM), etc.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

It should therefore be clearly understood that the order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure.

One or more examples of the present disclosure may be implemented using different combinations of software, firmware, and/or hardware. Thus, one or more of the techniques shown in the Figures (e.g., flowcharts) may be implemented using code and data stored and executed on one or more electronic devices or nodes (e.g., a workstation, a network element, etc.). Such electronic devices may store and communicate (internally and/or with other electronic devices over a network) code and data using computer-readable media, such as non-transitory computer-readable storage media (e.g., magnetic disks, optical disks, random access memory, read-only memory, flash memory devices, phase-change memory, etc.), transitory computer-readable transmission media (e.g., electrical, optical, acoustical or other form of propagated signals—such as carrier waves, infrared signals, digital signals), etc. In addition, some network elements or workstations, e.g., configured as servers, may typically include a set of one or more processors coupled to one or more other components, such as one or more storage devices (e.g., non-transitory or persistent machine-readable storage media) as well as storage database(s), user input/output devices (e.g., a keyboard, a touch screen, a pointing device, one or more imaging capturing devices and/or a display, etc.), and network connections for effectuating signaling and/or data transmission. The coupling of the set of processors and other components may be typically through one or more buses and bridges (also termed as bus controllers), arranged in any known (e.g., symmetric/shared multiprocessing) or heretofore unknown architectures. Thus, the storage device or component of a given electronic device or network element may be configured to store code and/or data for execution on one or more processors of that element, node or electronic device for purposes of implementing one or more techniques of the present disclosure.

At least some portions of the foregoing description may include certain directional terminology, such as, e.g., “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged mutatis mutandis, depending on the context, implementation, etc. Further, the features of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” All structural and functional equivalents to the elements of the above-described implementations that are known to those of ordinary skill in the art are expressly incorporated herein by reference and are intended to be encompassed by the claims appended below.

What is claimed is:

1. An integrated circuit (IC) fabrication tool, comprising:
at least one main chamber;
one or more processing chambers detachably coupled to the main chamber, each of the one or more processing chambers configured for effectuating a respective processing operation on a semiconductor wafer; and
at least one sensor chamber detachably coupled to the at least one main chamber, the at least one sensor chamber having a contactless sensor assembly for sensing sheet resistance of a process layer of the semiconductor wafer.

2. The IC fabrication tool as recited in claim 1, wherein the contactless sensor assembly comprises an eddy current sensor assembly including at least one sensor probe operative for facilitating a determination of the sheet resistance of the process layer.

3. The IC fabrication tool as recited in claim 2, wherein the at least one sensor chamber comprises:
a housing having a sealed terminus and an attachment terminus opposite to the sealed terminus, the attachment terminus configured to sealably attach to the at least one main chamber, the attachment terminus having an opening for facilitating transfer of the semiconductor wafer between the at least one main chamber and the at least one sensor chamber, the housing having one or more apertures for facilitating sealable mounting of the at least one sensor probe that is at least partially inserted into a space enclosed by the housing;
a lift assembly at least partially disposed in the housing, the lift assembly located proximate to the sealed terminus; and
a hub coupled to the lift assembly, the hub having a pair of opposing arms configured to hold the semiconductor wafer when transferred into the at least one sensor chamber from the at least one main chamber, the hub operating in association with the lift assembly for positioning the semiconductor process wafer proximate to the at least one sensor probe, the pair of opposing arms of the hub configured to retain the semiconductor wafer in position for measurement without using a chuck.

4. The IC fabrication tool as recited in claim 3, wherein the at least one main chamber comprises a first main chamber configured as a buffer chamber and a second main chamber configured as a transfer chamber, the buffer chamber coupled to the transfer chamber via a passage for allowing transfer of one or more semiconductor wafers therebetween, the at least one sensor chamber coupled to at least one of the buffer chamber and the transfer chamber, and a first portion of the one or more processing chambers coupled to the buffer chamber and a second portion of the one or more processing chambers coupled to the transfer chamber.

5. The IC fabrication tool as recited in claim 4, wherein the buffer chamber encloses a robotic wafer handler for transferring the semiconductor wafer between a load lock chamber and a processing chamber or between the processing chamber and the at least one sensor chamber or between two processing chambers.

6. The IC fabrication tool as recited in claim 4, wherein the transfer chamber encloses a robotic wafer handler for transferring the semiconductor wafer between a processing chamber and the at least one sensor chamber or between two processing chambers.

7. The IC fabrication tool as recited in claim 4, wherein the eddy current sensor assembly includes a first sensor probe containing an induction coil operative to cause eddy currents in the process layer responsive to a primary field generated by an alternating current (AC) input and a second sensor probe containing a pickup coil operative to generate a measurement signal responsive to a secondary field caused by the eddy currents, the measurement signal operative for facilitating a determination of the sheet resistance of the process layer of the semiconductor wafer, the semiconductor wafer horizontally disposed in the housing of the at least one sensor chamber

8. The IC fabrication tool as recited in claim 7, wherein the first and second sensor probes are located above the semiconductor wafer, the first and second sensor probes positioned adjacent to each other.

9. The IC fabrication tool as recited in claim 7, wherein the first and second sensor probes are located underneath the semiconductor wafer, the first and second sensor probes positioned adjacent to each other.

10. The IC fabrication tool as recited in claim 7, wherein the first and second sensor probes are located on opposite sides of the semiconductor wafer, the first and second sensor probes vertically aligned along a common axis.

11. The IC fabrication tool as recited in claim 4, wherein at least one processing chamber is configured to effectuate at least one of a physical vapor deposition (PVD) process, a chemical vapor deposition (CVD) process and an atomic layer deposition (ALD) process for forming the process layer.

12. The IC fabrication tool as recited in claim 4, wherein at least one processing chamber is configured to effectuate a rapid thermal annealing (RTA) process for modifying electrical properties of the process layer.

13. The IC fabrication tool as recited in claim 4, wherein the at least one sensor chamber includes a thermal sensor for obtaining a temperature measurement of the process layer.

14. A method of fabricating an integrated circuit (IC), the method comprising:
processing a semiconductor wafer in a fabrication flow having a sequence of process stages for creating at least one semiconductor die containing the IC, the semiconductor wafer forming a substrate for the IC, the sequence of process stages including at least one operation performed in a processing chamber of a fabrication tool with respect to a process layer of the semiconductor wafer; and
performing a sheet resistance measurement of the process layer using a contactless sensor assembly disposed in a sensor chamber integrated into the fabrication tool, the contactless sensor assembly comprising an eddy current sensor assembly including at least one sensor probe operative for sensing sheet resistance of the process layer.

15. The method as recited in claim 14, wherein the at least one operation comprises effectuating at least one of a physical vapor deposition (PVD) process, a chemical vapor deposition (CVD) process and an atomic layer deposition (ALD) process for forming the process layer.

16. The method as recited in claim 15, wherein the process layer is formed as a stack of conductive layers having an overall sheet resistance, each conductive layer having a corresponding sheet resistance measurement obtained by the contactless sensor assembly in a sequentially executed flow, the overall sheet resistance determined as a resultant sheet resistance based on respective sheet resistances of each conductive layer.

17. The method as recited in claim 14, wherein the at least one operation comprises to effectuating a rapid thermal annealing (RTA) process for modifying electrical properties of the process layer.

18. The method as recited in claim 14, wherein performing the sheet resistance measurement of the process layer comprises performing at least a first line scan as the semiconductor wafer is introduced into the sensor chamber by a blade coupled to a robotic arm, the first line scan terminating after the semiconductor wafer is brought to a halt at a predetermined location in the sensor chamber.

19. The method as recited in claim 18, wherein performing the sheet resistance measurement of the process layer further comprises performing a second line scan after the semiconductor wafer is transferred to a hub having a pair of opposing arms configured to hold the semiconductor wafer in position, the second line scan commencing as the semiconductor wafer is retracted from the sensor chamber by the robotic arm.
